(19) United States
(12) Patent Application Publication
(10) Pub. No.: US 2023/0343551 A1
(43) Pub. Date: Oct. 26, 2023

(54) SUBSTRATE PROCESSING METHOD

(71) Applicant: ASM IP Holding B.V., Almere (NL)

(72) Inventor: Shinya Yamada, Tokyo (JP)

(21) Appl. No.: 18/137,779

(22) Filed: Apr. 21, 2023

Related U.S. Application Data
(60) Provisional application No. 63/334,838, filed on Apr. 26, 2022.

(51) Int. Cl. C23C 16/36; C23C 16/40; C23C 16/34; C23C 16/04; C23C 16/455; C23C 16/505; H01J 37/32

(52) U.S. Cl. CPC H01J 37/32082; C23C 16/042; C23C 16/345; C23C 16/36; C23C 16/401; C23C 16/45536; C23C 16/505; H01J 2237/0203; H01J 2237/332

(57) ABSTRACT

Provided is a substrate processing method in which a liner layer is formed on the photo resist underlayer, followed by forming SiO₂ patterning layer thereon. According to the embodiment, the liner layer is formed by providing a silicon-containing layer, followed by inert gas activated by providing a high frequency RF power and a low frequency RF power together simultaneously. Thus, a loss of photo resist underlayer may be minimized within the range that does not affect the device performance and the wet etch properties and the width between fine patterns may be kept constant while the thickness of the liner layer is thin.

### CROSS-REFERENCE TO RELATED APPLICATIONS

This application claims priority to U.S. Provisional Pat. Application Serial No. 63/334,838 filed Apr. 26, 2022 titled SUBSTRATE PROCESSING METHOD, the disclosure of which is hereby incorporated by reference in its entirety.

### BACKGROUND

### 1. Technical Field

The disclosure relates to a method for processing a substrate, and more specifically to a method for minimizing a damage to underlayer of a substrate during processing using plasma in a reactor.

### 2. Description of the Related Arts

As the line width of a semiconductor circuit shrinks, the demand for low temperature processes to protect the semiconductor device from a thermal budget in conventional thermal processes has been increasing.

The plasma enhanced atomic layer deposition (PEALD) method has often been used for low temperature processes since the PEALD method uses a plasma to activate reactant gas and to facilitate a precise control of film thickness and uniformity on three-dimensional patterned structure at low temperature. For instance, the PEALD method facilitates a SiO₂ layer formation as a patterning layer at low temperature by activating an oxygen reactant gas by plasma.

When an oxide layer (e.g. SiO₂ layer) is used as a patterning layer deposited by PEALD method on a photo-resist (PR) patterned structure that includes carbon, a photo resist underlayer may be damaged due to a strong reactivity of oxygen radicals. The damage to the underlayer may continue until the SiO₂ layer is deposited to a certain thickness. In general, the underlayer damage less than 5 Å may be allowed as it may be within the range that does not significantly affect device performance. However, when the high intensity of RF power is applied to deposit a high wet etch resistant SiO₂ layer, the underlayer damage may significantly affect the device performance. Thus, in case of process condition to which high RF power is applied, a substrate processing method in which an underlayer damage is minimized and the damage is within a range that does not significantly affect the device performances may be necessary.

In conventional substrate processing method, a liner film as a protective layer may be formed on the photo resist to solve that issue. The liner layer is formed by adsorbing a source material on the photo resist without providing oxygen radicals. For instance, an aminosilane silicon source may be provided, followed by providing an activated Ar gas. The activated Ar gas dissociates the silicon source gas and the SiCN layer as a liner layer is formed on the photo resist. After that, a Si source and an oxygen plasma are provided alternately and sequentially to form SiO₂ layer as a patterning layer on the SiCN layer, and at least a part of the SiCN layer is converted into SiO₂ layer by reacting with the oxygen radicals. However, the photo resist underlayer is still damaged by highly active oxygen radicals. To solve that issue, the thickness of SiCN layer may be increased, but it also causes SiCN layer to be intermixed into SiO₂ layer and results in non-uniform SiO₂ layer properties throughout the SiO₂ layer. As a result, as two films with different compositions are stacked, the wet etch property of the film may not be uniform throughout the film. Also, as the semiconductor device shrinks more and the spacing between patterned structure of the semiconductor device becomes narrower, thinner SiO₂ patterning layer may be required to be formed on the patterned structure. Therefore when the SiCN layer becomes thick, the whole SiO₂ layer gets to include a SiCN layer and a SiO₂ layer together that is not fully converted from SiCN layer, thus the wet etch property of a SiO₂ layer is not uniform. In addition, the thickness of SiO₂ layer may exceed the required thin thickness. On the contrary, when the SiCN layer is thin, the photo resist underlayer may be directly damaged from active oxygen radicals, as shown by a loss of photo resist layer, a partial deformation of photo resist, or etc.

### SUMMARY

The present disclosure provides a method for minimizing a damage to underlayer of a substrate in substrate processing method using plasma in a reactor.

In one or more embodiment, the substrate processing method may include a first phase of forming a liner layer and a second phase of forming a deposition layer.

In one or more embodiment, the first phase of forming a liner layer is comprised of providing a first reactant and the third reactant to the patterned structure and forming a first source layer on the surface of the patterned structure.

In one or more embodiment, in the first phase of forming a liner layer, a low frequency RF power and a high frequency RF power are provided simultaneously to the first source layer while the third reactant is provided, and the first source layer is dissociated and converted into a second source layer by the activated third reactant.

In one or more embodiment, the second phase of forming a deposition layer is comprised of providing a first reactant and forming a third source layer on the liner layer, and providing a second reactant to the third source layer.

In one or more embodiment, in the second phase of forming a deposition layer, a high frequency RF power is provided while the second reactant is provided, and forming a compound by reacting the third source layer with the activated second reactant.

In one or more embodiment, at least a part of the liner layer is converted into the compound by the activated second reactant. In one more embodiment, a loss of patterned structure by the activated second reactant is below 5 Å.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart for substrate processing method of the disclosure.

FIG. 2 is a process timing graph in accordance with FIG. 1.

FIG. 3A is a view of underlayer loss in accordance with the existing process.

FIG. 3B is a view of underlayer loss in accordance with the existing process.

FIG. 3C is a view of underlayer loss in accordance with the substrate processing method of the disclosure.

FIG. 4 is a view of carbon loss according to various process conditions by the thickness of SiCN liner layer.

FIG. 5 is a view of forming SiO₂ patterning layer on the patterned structure comprising a photo resist.

FIG. 6 is a view of substrate processing apparatus for carrying out the substrate processing method of the disclosure.

### DETAILED DESCRIPTION OF THE DISCLOSURE

The disclosure relates to a method to solve the above-mentioned problems, and more specifically relates to a method of forming a liner layer having a thin thickness as a protective layer to minimize damage to an underlayer.

In the embodiment of the disclosure, dual frequency RF power may be provided to form a liner layer on a carbon-containing photo resist layer. More specifically, the liner layer may be formed by simultaneously providing a low frequency RF power and a high frequency RF power. The supply of low frequency RF power may have a technical advantage in that the density and the hardness of the liner layer may be improved, while minimizing the underlayer damage. The supply of high frequency RF power may have a technical advantage of promoting radical generation and achieving a high uniformity and a high film growth rate.

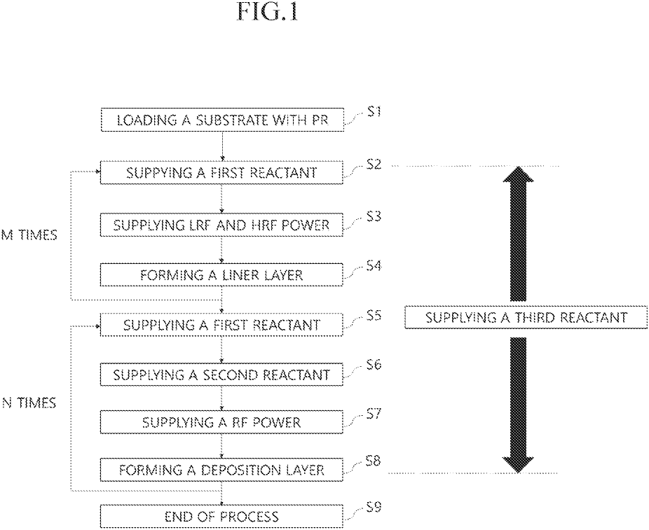

FIG. 1 shows a flowchart for a substrate processing method in accordance with the disclosure. More specifically, FIG. 1 shows a method for forming a liner layer and a deposition layer on a patterned structure formed on a substrate. The patterned structure may include at least one of photo resist; for example, the photo resist may comprise at least one of: carbon material (such as hard mask and spin-on carbon), or amorphous silicon. In FIG. 1, the patterned structure is illustrated as a photo resist as an example. The liner layer may be a protective layer and the deposition layer may be a patterning layer. The description of each step is provided in more detail as follows.

A first step S1: a substrate is loaded into a reactor. The substrate may include a patterned structure formed thereon and the patterned structure may comprise a carbon-containing photo resist.

A second step S2: a first source layer may be formed by supplying a first reactant. The first reactant may be a silicon-containing gas. For instance, the first reactant may comprise at least one of aminosilane, iodosilane, or halide. The first source layer may be formed by adsorbing the first reactant on the photo resist. And a third reactant may be continuously provided together throughout the process, that is, throughout the second step to the eighth step. The third reactant may comprise an inert gas such as Ar, He, or N₂. The third reactant may carry the first reactant to the substrate or facilitate the uniform supply of the first reactant to the reaction space.

A third step S3: a low frequency RF power and a high frequency RF power are provided simultaneously, resulting in activation of the third reactant.

A fourth step S4: The activated third reactant may dissociate the first source layer adsorbed on the photo resist. The dissociated first source layer may then be converted into a second source layer. The second source layer may consist of fragments of molecules of the first reactant. For instance, when an aminosilane source gas (as a first reactant) is provided and adsorbed on the photo resist as the first source layer, the second source layer may contain individual silicon elements, carbon elements, nitrogen elements, hydrogen elements, and fragments of ligands (such as alkyl group). The first source layer may be dissociated and converted into the second source layer, and the second source layer may be densified on the photo resist due to the ion bombardment effect of the activated third reactant.

The second step S2 to the fourth step S4 may be repeated a plurality of times, for instance, M times, and the third reactant may be continuously provided throughout the second step S2 to the fourth step S4. The second step S2 to the fourth step S4 may be referred to as the phase for forming a liner layer. The liner layer may be a protective layer to protect the photo resist underlayer from active species in the following phase for forming a deposition layer. In an exemplary embodiment, a purge step may be provided between the second step S2 and the third step S3, and between the third step S3 and the fourth step S4.

A fifth step S5: a third source layer may be formed on the second source layer by supplying the first reactant thereto. The first reactant may be a silicon-containing gas and may comprise at least one of aminosilane, iodosilane, or halide. The third source layer may be formed by adsorbing the first reactant on the second source layer. The third source layer may be the same material as the first source layer and the third reactant may be supplied together. The third reactant may be an inert gas such as Ar or N₂, and may carry the first reactant to the substrate and facilitate the uniform supply of the first reactant in the reaction space.

A sixth step S6: a second reactant may be provided to the reactor. The second reactant may not chemically react with the third source layer, but may chemically react with the third source layer when it is activated. Thus, the second reactant may be referred to as a reactive purge gas.

In one embodiment of the disclosure, the second reactant may contain oxygen. For instance, the second reactant may comprise least one of O₂, CO₂, N₂O, NO₂, O₃, H₂O, or the mixture thereof.

In another embodiment of the disclosure, the second reactant may contain nitrogen. For instance, the second reactant may comprise at least one of N₂, N₂O,NO₂, NH₃, N₂H₂, N₂H₄, or the mixture thereof. The third reactant may be continuously provided from the sixth step S6 to the seventh step S7.

A seventh step S7: high frequency RF power may be provided to the reactor. The high RF power may activate the second reactant. In alternative embodiment, a low frequency RF power and a high frequency RF power may be provided together.

An eight step S8: the activated second reactant and the third source layer chemically react with each other and form a deposition layer on the second source layer. In one embodiment, the deposition layer may be a patterning layer such as silicon oxide (SiOₓ) layer or silicon nitride (SiₓN_{y}) or any insulating material layer. In another embodiment, the sixth step S6 to the eight step S8 may be carried out simultaneously.

The fifth step S5 and the eight step S8 may be repeated a plurality of times, for instance, N times, and the third reactant may be continuously provided throughout the second step S5 to the fourth step S8. The fifth step S5 to the eight step S8 may be referred to as the phase for forming a deposition layer. In a selective embodiment, a purge step may be provided between the fourth step S4 and the fifth step S5, and between the fifth step S5 and the sixth step S6, and between the sixth step S6 and the seventh step S7, and between seventh step S7 and the eight step S8, and after the eight step S8. In another embodiment, the second reactant and the third reactant may be continuously provided throughout the fifth step S5 to the eight step S8.

A ninth step S9: after the first step S1 to S4, that is, a phase for forming a liner layer, and the fifth step S5 to the eight step S8, that is, a phase for forming a deposition layer are completed, the substrate processing process may end.

According to the embodiment of the disclosure described in FIG. 1, at least a part of the liner layer formed in the phase of forming a liner layer may be exposed to and chemically react with oxygen radicals provided during the phase for forming a deposition layer and the chemical composition of the part of the liner layer may be changed. For instance, the liner layer may include elements consisting of the second source layer as well as compound formed by reacting with the oxygen radicals.

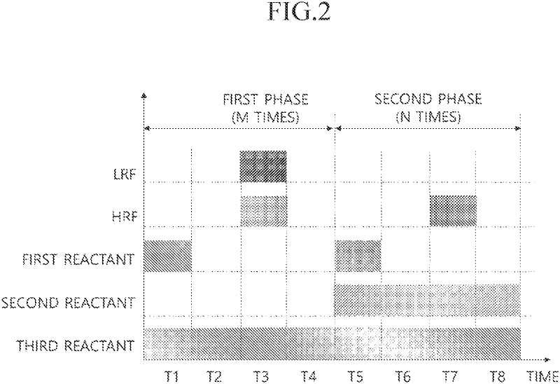

FIG. 2 is a view of the process timing graph according to an embodiment of the disclosure.

A first phase of FIG. 2 corresponds to a step 2 S2 to a step 4 S4 of FIG. 1, a phase for forming a liner layer. In more detail, the timing step T1 and the timing step T3 of FIG. 2 may correspond to the second step S2 and the third step S3 of FIG. 1, respectively.

A second phase of FIG. 2 corresponds to a step 5 S5 to a step 8 S8 of FIG. 2, a phase for forming a deposition layer. In more detail, the timing step T2 and T7 of FIG. 2 may correspond to the fifth step S5 and the seventh step S7 of FIG. 1, respectively. In an alternative embodiment, a low frequency RF power as well as a high frequency RF power may be provided together during the timing step T7 of the second phase. For instance, the low frequency RF power may be 300 kHz to 500 kHz RF power, or preferably 320 kHz to 470 kHz, or more preferably 340 kHz to 430 kHz. and the high frequency RF power may be 5 MHz to 60 MHz RF power, or preferably 7 MHz to 45 MHz, or more preferably 10 MHz to 30 MHz.

The first reactant provided during the timing steps T1 and T5 may contain silicon (Si) such as aminosilane, iodosilane, or halide. For instance, the first reactant may comprise: at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH_{2[}N(Et)(Me)]₂; AHEAD, Si₂(NHEt)₆; TEAS, Si(NHEt)₄; Si₃H₈ ; DCS, SiH₂Cl₂; SiHl₃; SiH₂l₂; or the mixture or derivatives thereof.

Thus, a SiCN liner layer as a protective layer may be formed on the photo resist during the first phase according to embodiments of FIG. 1 and FIG. 2.

The second reactant provided during the timing steps T2 and T5 of FIG. 2 may contain oxygen(O). For instance, the second reactant may comprise: at least one of O₂, O₃, CO₂, H₂O, NO₂, N₂O,or the mixture or derivatives thereof to form a compound, that is, an oxide layer. In another embodiment, the second reactant provided during the timing steps T2 and T5 of FIG. 2 may contain nitrogen(N). For instance, the second reactant may comprise at least one of N₂, N₂O, NO₂, NH₃, N₂H₂, N₂H₄, or the mixture thereof to form a compound, that is, a nitride layer.

The third reactant provided during the timing steps T1 to T8 may be an inert gas. For instance, the third reactant may comprise at least one of Ar, He, or N₂ or the mixture thereof.

The high frequency RF power provided during the phase for forming a liner layer may increase the ion density of the activated third reactant (such as Ar ions) and the low frequency RF power provided together may contribute to the film densification of the liner layer due to the ion bombardment effect. As a result, it contributes to minimizing damage to the underlying layer of the photoresist. Thus, the substrate processing method according to the disclosure may have a technical advantage in that: (1) the liner layer may be densified due to increased ion density; (2) the film conformality on the patterned structure may improve, and (3) the underlayer damage may decrease by providing the high frequency RF power and the low frequency RF power simultaneously.

According to the embodiment of FIG. 2, a part of the SiCN liner layer formed on the substrate may react with oxygen radicals during the deposition layer forming phase and the chemical composition may be changed. For instance, at least a part of SiCN liner layer may be converted into a SiO₂ layer.

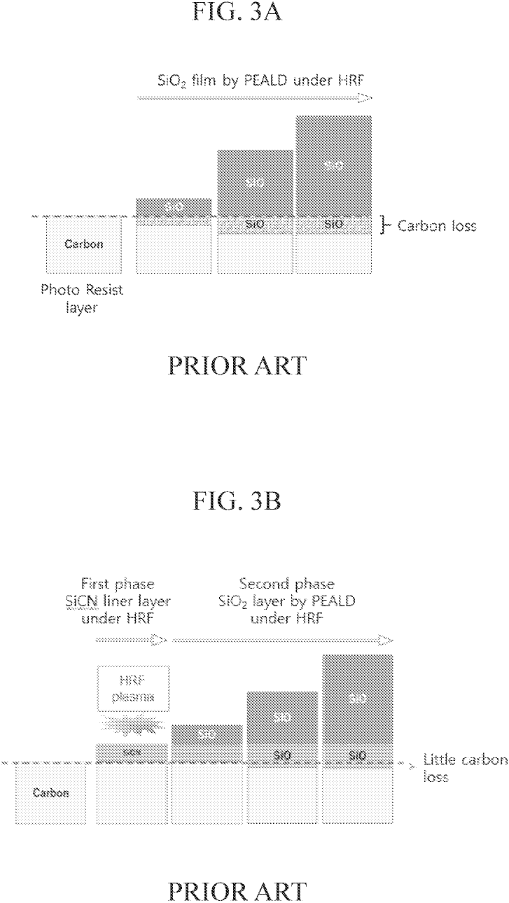

FIG. 3A, FIG. 3B and FIG. 3C show a degree of loss of underlayer according to the conventional substrate processing method and the substrate processing method of the disclosure.

FIG. 3A and FIG. 3B shows that a SiO₂ patterning layer is formed on the photo resist layer of the patterned structure by the conventional substrate processing method. FIG. 3C shows that a SiO₂ patterning layer is formed on the photo resist layer by the substrate processing method of the disclosure.

In FIG. 3A, when a SiO₂ layer is formed on the photo resist layer by PEALD by only providing high frequency RF power without forming a liner layer, a part of the liner layer which faces a SiO₂ layer is damaged by oxygen radicals, thus the carbon elements comprising the photo resist are lost and a SiO₂ layer is formed within the photo resist layer by oxygen radicals. In that case, in the subsequent selective etching process of SiO₂ layer, a part of the photo resist layer may be etched out together and the width between the fine patterns may not be uniform and that may lead to device defects.

In FIG. 3B, a 10 Å SiCN liner layer is formed on the photo resist layer by only providing a high frequency RF power during the first phase, followed by depositing SiO₂ patterning layer thereon during the second phase. When compared with FIG. 3a, the SiCN liner layer is converted into SiO₂ layer due to oxygen radicals and no residual SiCN layer remain in the converted SiO₂ layer due to 10 Å of thin SiCN layer thickness. But the photo resist layer is still damaged by oxygen radicals, thus carbon elements in the photo resist layer react with oxygen radicals to form CO₂ lost and the SiO₂ layer is formed within the photo resist layer. In that case, in the subsequent selective etching process of SiO₂ layer, a part of the photo resist layer may be etched out together and the width between the fine patterns may not be uniform and that may lead to device defects.

In FIG. 3C, a 10 Å SiCN liner layer is formed on the photo resist layer by providing a high frequency RF power and a low frequency RF power simultaneously during the first phase, followed by depositing SiO₂ patterning layer thereon during the second phase. When compared with FIG. 3A and FIG. 3B, the underlayer loss is significantly reduced within the range which does not affect the device performance even though the SiO₂ layer which was converted from SiCN liner layer is as thin as 10 Å. Therefore, the substrate processing method of the disclosure may have a technical advantage in that the loss of photo resist underlayer was significantly reduced and no residual SiCN layer remain in the SiO₂ layer. Thus, the uniform wet etch properties among SiO₂ patterning layer formed on patterned structure may be achieved and the width of fine pattern structures may be kept constant in the subsequent selective etching process, and the device defects may be prevented.

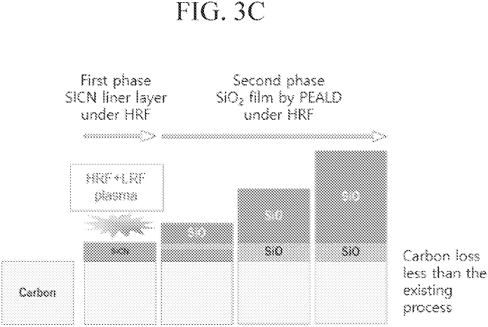

FIG. 4 is a view of carbon loss in the photo resist underlayer according to various process conditions by the thickness of SiCN liner layer when no liner layer is formed, when a liner layer is formed with only high frequency RF power provided and when a liner layer is formed with a high frequency RF power and a low frequency RF power provided simultaneously.

In FIG. 4, 600 Å of SiO₂ patterning layer is formed on the carbon hard mask film without a SiCN liner layer or with 5 Å, 10 Å and 20 Å of SiCN liner layer, respectively. When assuming a loss of underlayer less than 5Ådoes not affect the device performance, a process condition in which 10Åof SiCN liner layer is formed by providing a high frequency RF power and a low frequency RF power together, followed by forming SiO₂ patterning layer thereon by PEALD shows that the loss of underlayer is 4.2 Å. That is, below 5 Å, thus the underlayer loss may be controlled below the range that does not affect the device performance.

In addition, when the SiCN liner layer is thicker, for instance, 20 Å, and the SiCN liner layer is formed by providing only a high frequency RF power or a high frequency RF power and a low frequency RF power together, followed by forming SiO₂ patterning layer thereon by PEALD, the underlayer loss may be less than 5 Åand 1 Å,respectively. That is, below 5 Å, thus the underlayer loss may be controlled below the range that does not affect the device performance.

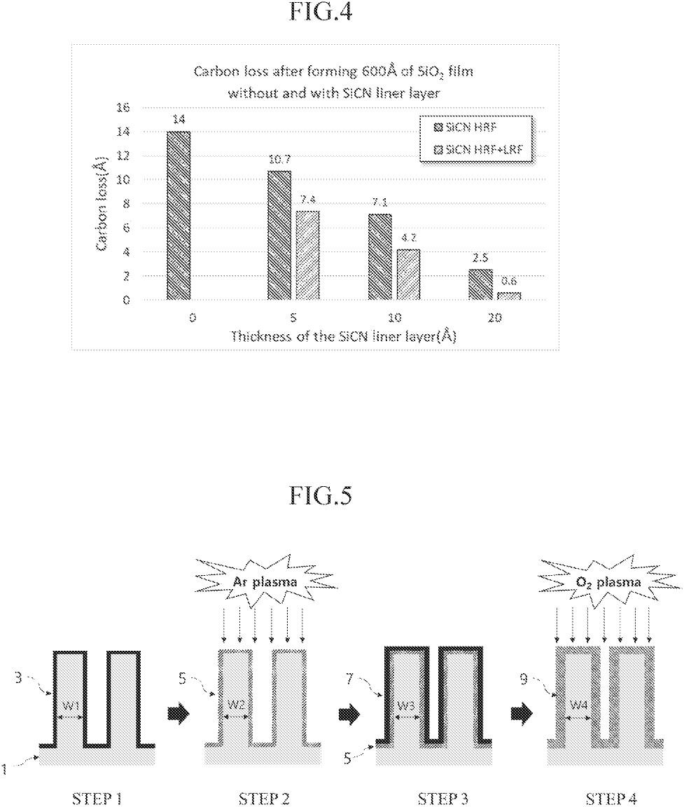

FIG. 5 illustrates a view of forming SiO₂ patterning layer on the patterned structure comprising a photo resist according to the disclosure.

In step 1 of FIG. 5, a silicon source gas and Ar gas are supplied to the patterned structure 1 formed on the substrate. The patterned structure may be a photo resist and consist of carbon elements. The silicon source molecules are thermally and conformally adsorbed on the surface of the patterned structure and form a source layer (a first source layer) 3 along the surface of the patterned structure. The Ar gas is continuously supplied throughout FIG. 5a to FIG. 5d.

In step 2 of FIG. 5, a low frequency RF power and a high frequency RF power are provided simultaneously and generate Ar plasma in-situ on the substrate. The activated Ar radicals and ions bombard and dissociate the silicon source molecules of the source layer 3, and the source layer 3 is converted into a second layer 5, that is, SiCN liner layer. The SiCN liner layer may have a thickness of 10 Å or greater than 10 Å. The second source layer is a mixture of constituents of the silicon source molecules such as silicon elements, carbon elements, hydrogen elements and alkyl groups consisting of ligands. The second source layer is densified by the bombardment effect of Ar radicals and ions.

In step 3 of FIG. 5, a silicon source gas and Ar gas are supplied to the adsorbed on the second source layer 5, that is, a liner layer, formed on the patterned structure1 and form a third source layer 7. The third source layer 7 may be the same as the first source layer 3. The silicon source molecules of the third source layer 7 are thermally and conformally adsorbed on the surface of the second source layer 5 along the surface of the patterned structure 1.

In step 4 of FIG. 5, an oxygen gas is supplied to the reactor and is activated by high frequency RF power supplied to the reactor. The third source layer reacts with the oxygen radicals and ions, and is converted into a deposition layer 9(i.e., SiO₂ layer). In this step, the second source layer 5, that is, SiCN liner layer, may be converted into the deposition layer SiO₂ by oxygen radicals and ions penetrated into the SiCN layer and no SiCN layer remains. But due to the shield effect by the increased thickness of SiO₂ layer formed by supplying a silicon source gas and oxygen gas repeatedly, the photo resist underlayer 1 is not lost. That is, the widths of the patterned structures are almost the same (W1=W2=W3=W4).

Table 1 shows a process condition for SiCN liner layer and SiO₂ deposition layer according to one embodiment of disclosure.

TABLE 1

a process condition for SiCN liner layer and SiO₂ deposition layer

| Process parameter | | Process condition | |
|---|---|---|---|
| | | SiCN liner layer | SiO₂ deposition layer |
| Heating block temperature(°C) | | 50 to100 (preferably 60 to 80) | 50 to 100 (preferably 60 to 80) |
| Gas flow rate (sccm) | Source carrier Ar | 1,000 to 8,000 (preferably 3,000 to 5,000) | 1,000 to 8,000 (preferably 3,000 to 5,000) |
| | Purge Ar | 0 | 1,000 to 2,000 (preferably 1,300 to 1,500) |
| | Purge N₂ | 1,000 to 2,000 (preferably 1,300 to 1,500) | 0 |
| | Reactant O₂ | 0 | 3,000 to 6,000 (preferably 4,000 to 5,000) |
| Process time (second) | Source feeding | 0.05 to 0.4(preferably 0.1 to 0.3) | 0.05 to 0.4(preferably 0.1 to 0.3) |
| | Source purge | 0.1 to 0.5 (preferably 0.2 to 0.4) | 0.1 to 0.5 (preferably 0.2 to 0.4) |
| | Reactant | 0.05 to 0.4 (preferably | 0.05 to 0.4 (preferably |
| Plasma power (W) | HRF (13.56 MHz) | 150 to 300 (preferably 200 to 250) | 150 to 500 (preferably 200 to 250) |
| | LRF (430 kHz) | 100 to 200 (preferably 125 to 175) | 0 to 500 (preferably 0 or 100 to 300) |
| Process pressure (Pa) | | 200 to 400 (preferably 250 to 350) | 200 to 500 (preferably 250 to 350) |
| Silicon source | | aminosilane | aminosilane |

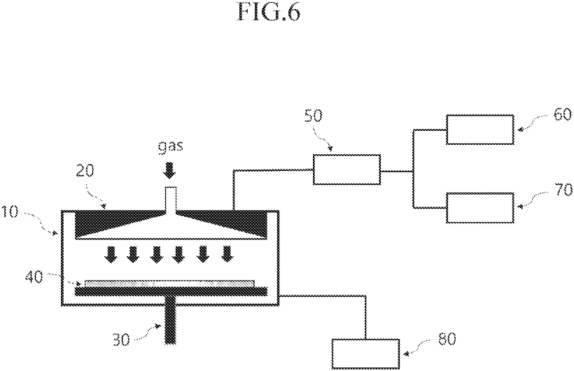

FIG. 6 is a schematic view of a substrate processing apparatus for carrying out the substrate processing method of the disclosure.

In FIG. 6, a substrate 40 may be disposed on a substrate support 30 and a gas supply unit 20 is provided to the reactor 10, configured to supply a gas to the substrate 40. The substrate support 30 may comprise a heating block supplying a heat energy to the substrate 40. The gas supply unit 20 may be a showerhead. Gas may be supplied to the substrate 40 through the gas supply unit 20 from outside.

The process gas is exhausted through an exhaust unit 80, which may be an exhaust pump. The gas supply unit 20 is connected to the RF power supply unit. The RF power supply unit may comprise: a matching network 50, a high frequency RF power generator 60, and/or a low frequency RF power generator 70. The RF power may be provided to the reactor and the intensity of RF power according to the disclosure may be controlled by step by programmable control unit such as PC controller (not shown).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing method, comprising,
a first phase of forming a liner layer on a patterned structure; and
a second phase of forming a deposition layer on the liner layer;
wherein the first phase of forming a liner layer is carried out by providing a dual frequency RF power.

2. The substrate processing method of claim 1, wherein,
the first phase for forming the liner layer comprises,
a first step of providing the substrate with a patterned structure to a reactor;
a second step of providing a first reactant to the substrate and forming a first source layer on the patterned structure;
a third step of providing a dual frequency RF power to the first source layer;
a fourth step of converting the first source layer into a second source layer;
wherein a third reactant is continuously provided throughout the second step to the fourth step.

3. The substrate processing method of claim 2, wherein,
the third step of providing a dual frequency RF power provides a low frequency RF power and a high frequency RF power simultaneously.

4. The substrate processing method of claim 3, wherein,
the low frequency of RF power ranges between 300 kHz to and 500 kHz; and
the high frequency of RF power ranges between 5 MHz and 60 MHz.

5. The substrate processing method of claim 2, wherein,
the first reactant comprises silicon, nitrogen, and carbon.

6. The substrate processing method of claim 5, wherein,
the first reactant comprises at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃Hs ; DCS, SiH₂Cl₂; SiHl₃; SiH₂l₂; or the mixture or derivatives thereof.

7. The substrate processing method of claim 2, wherein,
the first source layer is dissociated by the third reactant activated by the dual frequency RF power and is converted into the second source layer.

8. The substrate processing method of claim 7, wherein
the second source layer comprises: individual silicon elements, nitrogen element, carbon elements, or a mixture thereof.

9. The substrate processing method of claim 7, wherein,
the second source layer comprises a SiCN layer.

10. The substrate processing method of claim 2, wherein,
the third reactant comprises at least one of Ar, He, or N₂, or the mixture thereof.

11. The substrate processing method of claim 1, wherein,
the second phase of forming the deposition layer on the liner layer comprises,
a fifth step of providing a first reactant and forming a third source layer on the liner layer formed on the patterned structure;
a sixth step of providing a second reactant to the third source layer;
a seventh step of providing a high frequency RF power to the reactor and activating the second reactant; and
an eighth step for forming a compound by reacting the third source layer with the second reactant.

12. The substrate processing method of claim 11, wherein,
the third source layer is the same material as the first source layer.

13. The substrate processing method of claims 11, wherein,
the first reactant comprises at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃Hs ; DCS, SiH₂Cl₂; SiHl₃; SiH₂l₂; or the mixture or derivatives thereof.

14. The substrate processing method of claim 11, wherein,
the second reactant comprises at least one of O₂, O₃, CO₂, H₂O, NO₂, N₂O, or the mixture thereof.

15. The substrate processing method of claim 11, wherein,
the second reactant comprises at least one of N2, N₂O, NO₂, NH3, N2H2, N2H4, or the mixture thereof.

16. The substrate processing method of claim 11, wherein,
the compound comprises at least one of silicon oxide or silicon nitride.

17. The substrate processing method of claim 11, wherein,
at least a part of the liner layer is converted into a compound by activated second reactant.

18. The substrate processing method of claim 17, wherein,
the whole liner layer is converted into a compound by activated second reactant.

19. The substrate processing method of claim 1, wherein,
the thickness of the liner layer is 10 Å or greater than 10 Å.

20. The substrate processing method of claim 11, wherein,
a loss of the patterned structure is below 5 Å.

21. The substrate processing method of claim 1, wherein,
the patterned structure comprises at least one of: a photo resist, carbon material, or amorphous silicon.

22. The substrate processing method of claim 11, wherein,
the widths of the patterned structures are almost the same.
